(19) United States
(12) Patent Application Publication
(10) Pub. No.: US 2025/0248247 A1
(43) Pub. Date: Jul. 31, 2025

(54) ARRAY SUBSTRATE, DISPLAY DEVICE, AND METHOD FOR MANUFACTURING AN ARRAY SUBSTRATE

(71) Applicants: YUNNAN INVENSIGHT OPTOELECTRONICS TECHNOLOGY CO., LTD., Kunming, Yunnan (CN); BOE TECHNOLOGY GROUP CO., LTD., Beijing (CN)

(72) Inventors: YUNLONG LI, Beijing (CN); QINGSHAN SHAN, Beijing (CN); PENGCHENG LU, Beijing (CN); WEI LIU, Beijing (CN)

(73) Assignees: YUNNAN INVENSIGHT OPTOELECTRONICS TECHNOLOGY CO., LTD., Kunming, Yunnan (CN); BOE TECHNOLOGY GROUP CO., LTD., Beijing (CN)

(21) Appl. No.: 18/855,050

(22) PCT Filed: Feb. 6, 2024
(86) PCT No.: PCT/CN2024/076350

§ 371 Date: Oct. 8, 2024

(30) Foreign Application Priority Data
Mar. 13, 2023 (CN) 202310238214.1

(51) Int. Cl. H10K 59/131; H10K 59/12; H10K 59/122; H10K 71/60

(52) U.S. Cl. CPC H10K 59/131; H10K 59/1201; H10K 59/122; H10K 71/60

(57) ABSTRACT

The present disclosure relates to an array substrate, a display device and a method for manufacturing the array substrate. The array substrate having a display area and a peripheral area at least partially surrounding the display area, the array substrate includes a base substrate; a first conductive layer on the base substrate and located in the peripheral area; a second conductive layer on the base substrate and located in the display area; a pixel define layer on the first conductive layer and the second conductive layer; a first opening in the pixel define layer and exposing a portion of a surface of the first conductive layer away from the base substrate; a second opening in the pixel define layer and exposing a portion of a surface of the second conductive layer away from the base substrate, wherein a width of a bottom of the first opening is greater than a width of a bottom of the second opening.

### CROSS-REFERENCE TO RELATED APPLICATION

This patent application is a National Stage Entry of PCT/CN2023/138346 filed on Dec. 13, 2023 which claims the priority of Chinese application number 202310238214.1 filed on Mar. 13, 2023, the disclosures of which is incorporated by reference herein in its entirety as part of the present application.

### FIELD

The present invention relates to a field of display technology, and more particularly, to an array substrate, a display device, and a method for manufacturing an array substrate.

### BACKGROUND

Organic Light-Emitting Diode (OLED) display panels have the advantages of self-luminescence, high efficiency, bright colors, etc., and have gradually been used in large-area display, lighting, and automotive display.

### BRIEF DESCRIPTION

An embodiment of the present invention provides an array substrate. The array substrate has a display area and a peripheral area at least partially surrounding the display area, and the array substrate includes a base substrate, and the array substrate also includes:
a first conductive layer on the base substrate and located in the peripheral area;
a second conductive layer on the base substrate and located in the display area;
a pixel define layer on the first conductive layer and the second conductive layer;
a first opening in the pixel define layer and exposing a portion of a surface of the first conductive layer away from the base substrate;
a second opening in the pixel define layer and exposing a portion of a surface of the second conductive layer away from the base substrate, wherein a width of a bottom of the first opening is greater than a width of a bottom of the second opening;
a third conductive layer on the pixel define layer in the display area, wherein the third conductive layer also extends into the first opening and contacts a side of the first conductive layer away from the base substrate;
a light-emitting functional layer between the second conductive layer and the third conductive layer, wherein the light-emitting functional layer contacts a side of the first conductive layer away from the base substrate.

In some embodiments, a contact area between the light-emitting functional layer and the side of the first conductive layer away from the base substrate is smaller than a contact area between the third conductive layer and a side of the first conductive layer away from the base substrate.

In some embodiments, the first opening and the second opening are formed by a single patterning process.

In some embodiments, an angle between the first opening and the base substrate is consistent with an angle between the second opening and the base substrate.

In some embodiments, the angle between the first opening and the base substrate is between 80° and 90°.

In some embodiments, a width of the first opening is greater than a height of the first opening.

In some embodiments, the first conductive layer and the second conductive layer are on the same layer.

In some embodiments, the second conductive layer includes a plurality of second sub-conductive portions spaced apart from each other, and the array substrate further includes:
a fourth conductive layer on the base substrate, the fourth conductive layer having a first sub-portion located in the peripheral area and at least one second sub-portion spaced apart from the first sub-portion and located in the display area;
a passivation layer on the fourth conductive layer;
a third via hole and a fourth via hole in the passivation layer, wherein the third via hole is in the peripheral area, and the fourth via hole is in the display area;
a conductive portion in the third via hole and in the fourth via hole, wherein the first conductive layer is electrically connected to the first sub-portion through the third via hole, and wherein the third conductive layer is electrically connected to the second sub-portion through the fourth via hole.

In some embodiments, an orthographic projection of the first conductive layer on the base substrate at least partially overlaps with an orthographic projection of the first sub-portion on the base substrate with a first overlapping area, wherein an orthographic projection of the third via hole on the base substrate is in the first overlapping area; and an orthographic projection of the second conductive layer on the base substrate overlaps at least partially with an orthographic projection of the second sub-portion on the base substrate with a second overlapping area, wherein an orthographic projection of the fourth via hole on the base substrate is in the second overlapping area.

In some embodiments, a side of the light-emitting functional layer close to the peripheral area and a surface of the light-emitting functional layer away from the base substrate are connected by a smooth curved surface.

In some embodiments, the first opening surrounds the display area.

An embodiment of the present invention further provides a display device. The display device includes the array substrate as described above.

An embodiment of the present invention further provides a method for manufacturing an array substrate, the array substrate having a display area and a peripheral area at least partially surrounding the display area, the method includes providing a base substrate, and further includes:
forming a first conductive layer in the peripheral area and on the base substrate;
forming a second conductive layer in the display area and on the base substrate;
forming a pixel define layer on the first conductive layer and the second conductive layer;
forming a first opening in the pixel define layer to expose a portion of a surface of the first conductive layer away from the base substrate;
forming a second opening in the pixel define layer to expose a portion of a surface of the second conductive layer away from the base substrate, wherein a width of the bottom of the first opening is greater than a width of the bottom of the second opening;

In some embodiments, the method further includes forming a third conductive layer in the display area on the pixel define layer, wherein the third conductive layer also extends into the first opening and contacts a side of the first conductive layer away from the base substrate;
forming a light-emitting functional layer between the second conductive layer and the third conductive layer, wherein the light-emitting functional layer contacts a side of the first conductive layer away from the base substrate.

In some embodiments, forming the third conductive layer includes forming the third conductive layer by evaporation using a mask having an opening corresponding to the first opening.

In some embodiments, the first opening and the second opening are formed by a single patterning process.

In some embodiments, an angle between the first opening and the base substrate is substantially consistent with an angle between the second opening and the base substrate.

In some embodiments, the angle between the first opening and the substrate is between about 80° and 90°.

In some embodiments, forming the first conductive layer, the second conductive layer, the pixel define layer, the first opening and the second opening includes:
forming a first conductive material layer on the base substrate;
patterning the first conductive material layer to form the first conductive layer and the second conductive layer;
forming a pixel define material layer on the first conductive layer and the second conductive layer;
patterning the pixel define material layer to form the first opening and the second opening.

In some embodiments, the method further includes:
before forming the first conductive material layer,
a. forming a fourth conductive material layer on the base substrate;
b. patterning the fourth conductive material layer to form a fourth conductive layer, wherein the fourth conductive layer has a first sub-portion in the peripheral area and at least one second sub-portion in the display area and spaced apart from the first sub-portion;
c. forming a passivation layer on the fourth conductive layer;
d. patterning the passivation layer to form a third via hole and a fourth via hole, wherein the third via hole exposes a portion of a surface of the first sub-portion away from the base substrate, and the fourth via hole exposes a portion of a surface of the second sub-portion away from the base substrate;
e. forming a conductive portion in the third via hole and the fourth via hole, wherein the first conductive layer is connected to the first sub-portion through the third via hole, and wherein the second conductive layer is electrically connected to the second sub-portion through the fourth via hole; and
after forming the first opening and the second opening,
f. forming a light-emitting functional layer on the pixel define layer;
g. forming the third conductive portion on the light-emitting functional layer

### BRIEF DESCRIPTION OF THE DRAWINGS

In order to explain the technical solutions of the embodiments of the present disclosure more clearly, the drawings of the embodiments will be briefly described below. It should be understood that the drawings described below only relate to some embodiments of the present disclosure, instead of being a limit to the present disclosure, in which:

FIG. 1 is a schematic view of an array substrate according to an embodiment of the present invention;

FIG. 2 is a schematic view of an array substrate according to an embodiment of the present invention;

FIG. 3 is a schematic view of an array substrate according to an embodiment of the present invention;

FIG. 4 is a schematic view of an array substrate according to an embodiment of the present invention;

FIG. 5 is a schematic view of a display device according to an embodiment of the present invention;

FIG. 6 is a schematic view of a method for manufacturing an array substrate having a display area and a peripheral area at least partially surrounding the display area according to an embodiment of the present invention;

FIG. 7 is a schematic view of a method for manufacturing an array substrate according to an embodiment of the present invention;

FIG. 8 is a schematic view of a method for manufacturing an array substrate according to an embodiment of the present invention;

FIG. 9 is a schematic view of a method for manufacturing an array substrate according to an embodiment of the present invention;

FIG. 10 is a schematic view of a method for manufacturing an array substrate according to an embodiment of the present invention.

FIG. 11 is a schematic view of a method for manufacturing an array substrate according to an embodiment of the present invention;

FIG. 12 is a schematic view of a method for manufacturing an array substrate according to an embodiment of the present invention;

FIG. 13 is a schematic view of a method for manufacturing an array substrate according to an embodiment of the present invention;

FIG. 14 is a schematic view of a method for manufacturing an array substrate according to an embodiment of the present invention;

FIG. 15 is a schematic view of a method for manufacturing an array substrate according to an embodiment of the present invention;

FIG. 16 is a schematic view of a method for manufacturing an array substrate according to an embodiment of the present invention;

FIG. 17 is a schematic view of a method for manufacturing an array substrate according to an embodiment of the present invention;

FIG. 18 is a schematic view of a method for manufacturing an array substrate according to an embodiment of the present invention;

FIG. 19 is a schematic view of an array substrate according to an embodiment of the present invention.

### DETAILED DESCRIPTION

In order to make the objectives, technical solutions, and advantages of the embodiments of the present disclosure clearer, the technical solutions of the embodiments of the present disclosure will be described clearly and completely in conjunction with the accompanying drawings. Obviously, the described embodiments are part of the embodiments of the present disclosure, rather than all of the embodiments. Based on the described embodiments of the present disclosure, all other embodiments obtained by those skilled in the art without creative labor are also belonging to the protection scope of the present disclosure.

When the elements and the embodiments thereof of the present application are introduced, the articles “a/an”, “one”, “the” and “said” are intended to represent the existence of one or more elements. The expressions “comprise”, “include”, “contain” and “have” are intended as inclusive and mean that there may be other elements besides those listed.

For purposes of the description hereinafter, the terms “upper”, “lower”, “right”, “left”, “vertical”, “horizontal”, “top”, “bottom”, and derivatives thereof shall relate to the invention, as it is oriented in the drawing figures. The terms “overlying”, “atop”, “positioned on” or “positioned atop” means that a first element, such as a first structure, is present on a second element, such as a second structure, wherein intervening elements, such as an interface structure, e.g. interface layer, may be present between the first element and the second element. The term “direct contact” means that a first element, such as a first structure, and a second element, such as a second structure, are connected with or without any additional elements at the interface of the two elements.

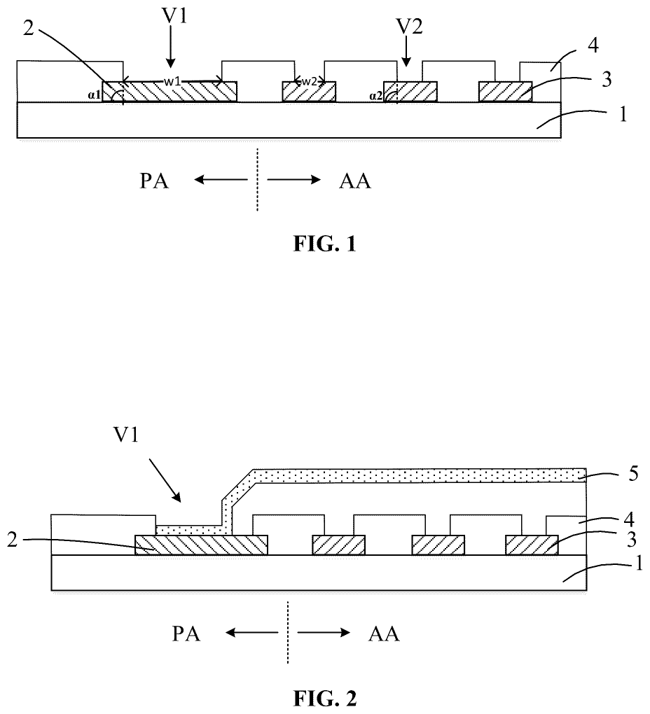

FIG. 1 is a schematic view of an array substrate according to an embodiment of the present invention. As shown in FIG. 1, the array substrate according to an embodiment of the present invention may have a display area AA and a peripheral area PA at least partially surrounding the display area, and the array substrate may include a base substrate 1, a first conductive layer 2 on the base substrate 1 and located in the peripheral area PA, a second conductive layer 3 on the base substrate 1 and located in the display area AA, a pixel define layer 4 on the first conductive layer 2 and the second conductive layer 3, a first opening V1 in the pixel define layer 4 and exposing a portion of the surface of the first conductive layer 2 away from the base substrate 1, and a second opening V2 in the pixel define layer 4 and exposing a portion of the surface of the second conductive layer 3 away from the base substrate 1. Wherein, in a direction parallel to the surface of the base substrate 1, a width w1 of the bottom of the first opening V1 is greater than a width w2 of the bottom of the second opening V2.

The array substrate according to an embodiment of the present invention can remove the dummy area of the conventional array substrate, realize a narrower frame design, improve product performance, simplify the process flow and reduce process costs.

FIG. 2 is a schematic view of an array substrate according to an embodiment of the present invention. As shown in FIG. 2, the array substrate according to an embodiment of the present invention may include a third conductive layer 5. The third conductive layer 5 is located on the pixel define layer 4 in the display area AA, and the third conductive layer 5 also extends into the first opening V1 and contacts a side of the first conductive layer 2 away from the substrate. The third conductive layer 5 can be used as the cathode of the pixel unit of the array substrate, and the second conductive layer 3 can be used as the anode of the pixel unit of the array substrate. The first conductive layer 2 can be used to send conduct electrical signals to the third conductive layer 5.

The embodiment of the present invention can provide a solution that facilitates the contact of the first conductive layer 2 and the third conductive layer 5, simplifies the manufacturing process and reduces the manufacturing cost.

In some embodiments, the first opening V1 and the second opening V2 are formed by a single patterning process. Such a solution does not require two patterning processes as in some examples, and can improve product performance while simplifying the process flow and reducing the process cost.

As shown in FIGS. 1 and 2, the angle α1 between the first opening V1 and the base substrate 1 may be consistent with the angle α2 between the second opening V2 and the base substrate. In some embodiments, the angle between the first opening V1 and the base substrate 1 can be between about 80° and 90°. For example, the angle can be 82°, 85°, 87° or 90°. Such an angle can prevent crosstalk of pixel units and ensure the contact of the first conductive layer 2 and the third conductive layer 5. At the same time, two patterning processes are not required, which can reduce the process flow, reduce costs and improve product yield.

In some embodiments, the width of the first opening in a direction parallel to the surface of the substrate is greater than the height of the first opening in the direction perpendicular to the surface of the substrate. This can also better achieve the technical effects of preventing crosstalk of pixel units and ensuring the contact of the first conductive layer 2 and the third conductive layer 5, reducing the process flow, reducing costs and improving product yield.

In some embodiments, the first conductive layer 2 and the second conductive layer 3 can be in the same layer. Here, “in the same layer” means that the two can be formed by the same film layer. For example, the first conductive layer and the second conductive layer can include the same material. For example, the first conductive layer and the second conductive layer can include at least one of the following materials: magnesium, zinc, aluminum or a mixture thereof.

FIG. 3 is a schematic view of an array substrate according to an embodiment of the present invention. As shown in FIG. 3, the second conductive layer 3 includes a plurality of second sub-conductive portions 31 separated from each other by a planarization layer 6, and the first conductive layer can also be separated from the second conductive layer 3 by the planarization layer 6.

As shown in FIG. 3, the array substrate according to the embodiment of the present invention may further include a fourth conductive layer 7 on the base substrate 1, the fourth conductive layer 7 having a first sub-portion 71 located in the peripheral area PA and at least one second sub-portion 72 located in the display area AA and spaced from the first sub-portion 71; a passivation layer 8 on the fourth conductive layer 7; a third via hole V3 and a fourth via hole V4 in the passivation layer 8, the third via hole being in the peripheral area, and the fourth via hole being in the display area; a conductive portion 9 in the third via hole V3 and in the fourth via hole V4, wherein the first conductive layer 2 is electrically connected to the first sub-portion 71 through the third via hole V3, and the third conductive layer is electrically connected to the second sub-portion 72 through the fourth via hole V4.

The orthographic projection of the first conductive layer 2 on the base substrate overlaps at least partially with the orthographic projection of the first sub-portion 71 on the base substrate with a first overlapping area; the orthographic projection of the third via hole on the base substrate is located in the first overlapping area; the orthographic projection of the second conductive layer 3 on the base substrate overlaps at least partially with the orthographic projection of the second sub-portion 72 on the base substrate with a second overlapping area; the orthographic projection of the fourth via hole on the base substrate is located in the second overlapping area.

The array substrate according to an embodiment of the present invention may also include a light-emitting functional layer 10 disposed between the second conductive layer 3 and the third conductive layer 5.

The light-emitting functional layer 10 may include a layer for realizing the function of light emission. For example, the light-emitting functional layer may include a hole injection layer (HIL), a hole transport layer (HTL) on the hole injection layer, a light-emitting layer (EML) on the hole transport layer, an electron transport layer (ETL) on the light-emitting layer, and an electron injection layer (EIL) on the electron transport layer.

The light-emitting functional layer 10 covers the second opening V2 to form a plurality of light-emitting units, and the light-emitting functional layer (e.g., organic light-emitting layer) contacts the first conductive layer 2 and covers a portion of the structure of the first conductive layer. Such a design can make the peripheral area narrower and eliminate the dummy area. During the manufacturing process, the opening of the mask corresponding to the light-emitting functional layer can be designed as on the third conductive layer (e.g., cathode). When the light-emitting functional layer such as the organic light-emitting layer is evaporated, the light-emitting functional layer can be directly evaporated and contact the inner side of the third conductive layer (such as, a cathode), so that the third conductive layer (e.g., cathode) can be smoothly overlapped on the cathode ring with the height difference of the light-emitting functional layer, thereby avoiding an etching of the cathode ring area.

FIG. 19 is a schematic view of an array substrate according to an embodiment of the present invention. As shown in FIG. 19, the side of the light-emitting functional layer 5 close to the peripheral area PA is connected to a surface away from the base substrate by a smooth curved surface.

It should be noted that FIG. 1-3 takes the array substrate having one first opening as an example, and the number of first openings is not limited to one. The first opening(s) can surround the display area.

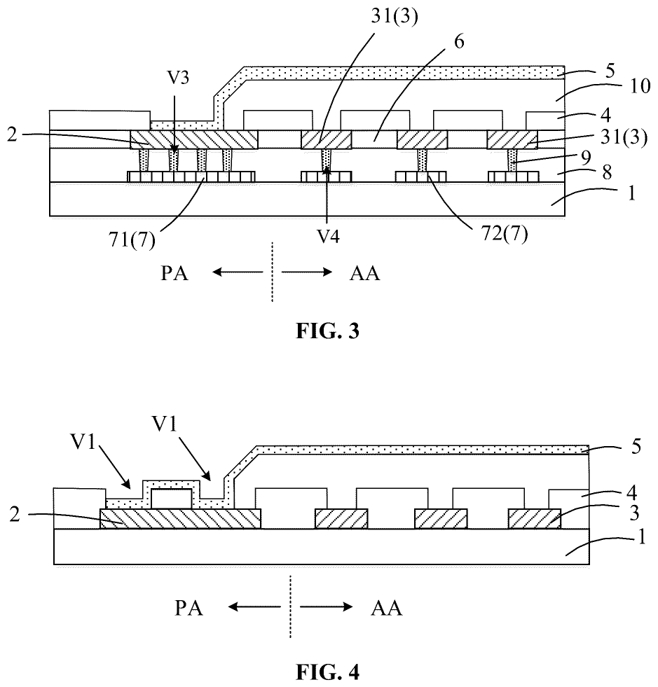

FIG. 4 is a schematic view of an array substrate according to an embodiment of the present invention. As shown in FIG. 4, the array substrate may include at least two first openings. The number of second openings may also be set according to actual needs.

The shapes of the first opening, the second opening, the third via hole and the fourth via hole are not limited to the specific shapes shown in the figures. In some embodiments, it may be a polygon, for example, a triangle, a quadrilateral or a pentagon. In other embodiments, it may be a circle or an ellipse.

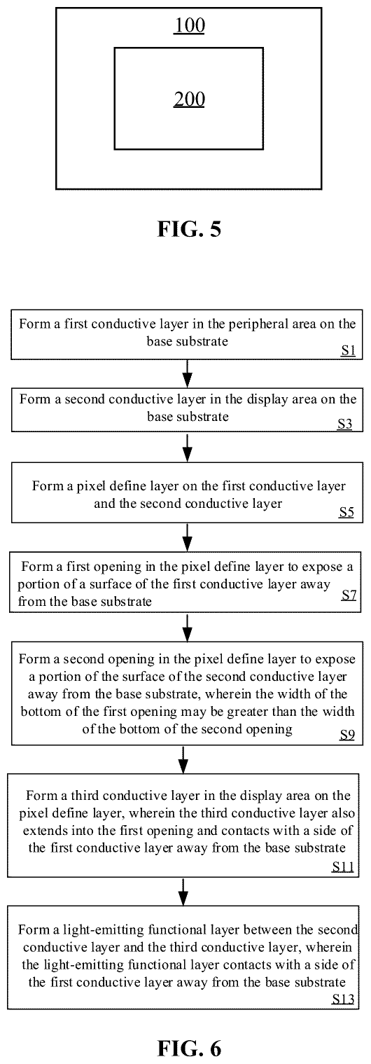

FIG. 5 is a schematic view of a display device according to an embodiment of the present invention. As shown in FIG. 5, the display panel 100 according to an embodiment of the present disclosure may include an array substrate 200. The array substrate 200 may be the array substrate shown in FIGS. 1-4.

FIG. 6 is a flow view of a method for manufacturing an array substrate having a display area and a peripheral area at least partially surrounding the display area according to an embodiment of the present invention. As shown in FIG. 6, the method for manufacturing an array substrate according to an embodiment of the present invention may include:
S1, forming a first conductive layer in the peripheral area on the base substrate;
S3, forming a second conductive layer in the display area on the base substrate;
S5, forming a pixel define layer on the first conductive layer and the second conductive layer;
S7, forming a first opening in the pixel define layer to expose a portion of the surface of the first conductive layer away from the base substrate;
S9, forming a second opening in the pixel define layer to expose a portion of the surface of the second conductive layer away from the base substrate, wherein the width of the bottom of the first opening may be greater than the width of the bottom of the second opening;
S11, forming a third conductive layer in the display area on the pixel define layer, wherein the third conductive layer also extends into the first opening and contacts a side of the first conductive layer away from the base substrate;
S13, forming a light-emitting functional layer between the second conductive layer and the third conductive layer, wherein the light-emitting functional layer contacts a side of the first conductive layer away from the base substrate.

The method for manufacturing an array substrate according to an embodiment of the present invention can provide a higher performance array substrate and remove the dummy area of a conventional array substrate, realize a narrower frame design, and can also simplify the process flow and reduce the process cost.

In some embodiments, the method for manufacturing an array substrate may further include forming a third conductive layer in the display area on the pixel define layer, wherein the third conductive layer also extends into the first opening and contacts the first conductive layer. Such an embodiment may provide a solution that facilitates the contact of the first conductive layer and the third conductive layer, simplifies the manufacturing process, and reduces the manufacturing cost.

In some embodiments, forming the third conductive layer includes forming the third conductive layer by evaporation using a mask having an opening corresponding to the first opening.

In some embodiments, the first opening and the second opening are formed by a single patterning process. Such a solution does not require two patterning processes as in some examples, and can simplify the process flow and reduce the process cost while improving product performance.

In some embodiments, the angle between the first opening and the base substrate may be consistent with the angle between the second opening and the base substrate. In some embodiments, the angle between the first opening and the base substrate may be between 80° and 90°. In some embodiments, the angle between the first opening V1 and the substrate 1 may be between about 80° and 90°. For example, the angle may be 82°, 85°, 87°, or 90°. Such an angle can prevent crosstalk among pixel units and ensure the contact of the first conductive layer 2 and the third conductive layer 5. At the same time, two patterning processes are not required, which can reduce the process flow, reduce costs and improve product yield.

In some embodiments, the width of the first opening in the direction parallel to the surface of the substrate is greater than the height of the first opening in the direction perpendicular to the surface of the substrate. This can also better achieve the technical effects of preventing crosstalk between pixel units and ensuring the contact of the first conductive layer 2 and the third conductive layer 5, reducing the process flow, reducing costs and improving product yield.

In some embodiments, the first conductive layer 2 and the second conductive layer 2 can be arranged in the same layer. Here, “in the same layer” means that the two can be formed by the same film layer. For example, the first conductive layer and the second conductive layer can include the same material. For example, the first conductive layer and the second conductive layer can include at least one of the following materials: magnesium, zinc, aluminum or a mixture thereof.

In some embodiments, forming the first conductive layer, the second conductive layer, the pixel define layer, the first opening, and the second opening includes:
S21, forming a first conductive material layer on a base substrate;
S23, patterning the first conductive material layer to form the first conductive layer and the second conductive layer;
S25, forming a pixel define material layer on the first conductive layer and the second conductive layer;
S27, patterning the pixel define material layer to form a first opening and a second opening.

In some embodiments, the method for manufacturing an array substrate may further include:
before forming the first conductive material layer,
S31, forming a fourth conductive material layer on the base substrate;
S33, patterning the fourth conductive material layer to form a fourth conductive layer, wherein the fourth conductive layer has a first sub-portion located in the peripheral area and at least one second sub-portion located in the display area and spaced apart from the first sub-portion; S35, forming a passivation layer on the fourth conductive layer;
S37, patterning the passivation layer to form a third via hole and a fourth via hole;
S39, forming a conductive portion in the third via hole and the fourth via hole, wherein the first conductive layer is connected to the first sub-portion through the third via hole, and the second conductive layer is electrically connected to the second sub-portion through the fourth via hole; and after forming the first opening and the second opening,
S41, forming a light-emitting functional layer on the pixel define layer; S43, forming the third conductive portion on the light-emitting functional layer.

The light-emitting functional layer may include a layer for realizing a light-emitting function. For example, the light-emitting functional layer may include a hole injection layer (HIL), a hole transport layer (HTL) on the hole injection layer, a light-emitting layer (EML) on the hole transport layer, an electron transport layer (ETL) on the light-emitting layer, and an electron injection layer (EIL) on the electron transport layer.

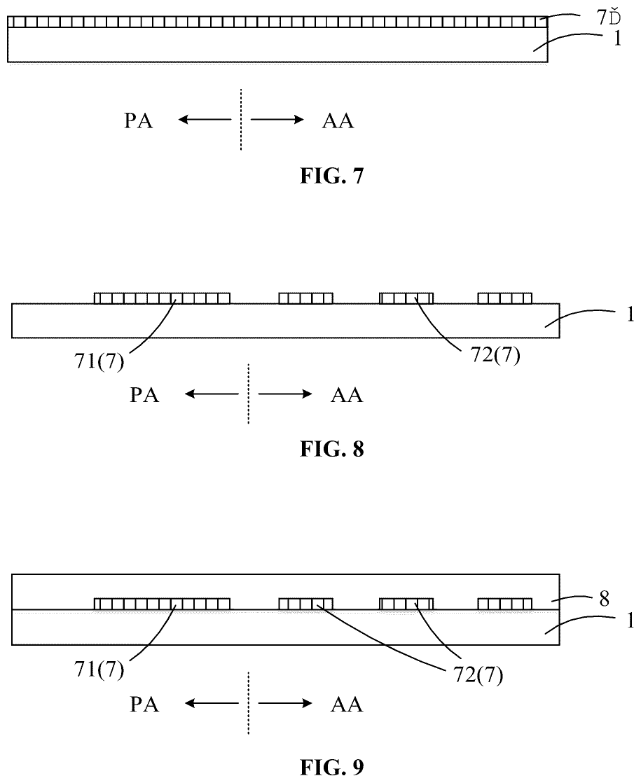

FIGS. 7 to 18 are schematic views of a method for manufacturing an array substrate according to an embodiment of the present invention. As shown in FIGS. 7 to 18, the method for manufacturing an array substrate according to an embodiment of the present invention may include:

As shown in FIG. 7, forming a fourth conductive material layer 7′ on the base substrate 1. For example, a metal layer may be deposited on the base substrate to form the fourth conductive material layer.

In some embodiments, the base substrate may include a semiconductor material. The term “semiconductor material” refers to a material having a conductivity value between a conductor (e.g., copper) and an insulator (e.g., glass). The semiconductor material may exist as an elemental material or a composite material. Examples of semiconductor materials that can be used as base substrates include Si, SiGe, SiGeC, SiC, Ge alloys, III/V compound semiconductors, or II/VI compound semiconductors. In other embodiments of the present invention, the base substrate may include a combination of semiconductor material and dielectric material, for example, the base substrate may be a material stack of a silicon dioxide layer and a silicon layer stacked from bottom to top. In still other embodiments, the base substrate may include a ceramic material, an elemental metal, an alloy of elemental materials, or any other material or material combination.

As shown in FIG. 8, the fourth conductive material layer 7 ‘is patterned to form a fourth conductive layer 7, wherein the fourth conductive layer 7 has a first sub-portion 71 located in the peripheral area PA and at least one second sub-portion 72 located in the display area AA and spaced apart from the first sub-portion 71.

As shown in FIG. 9, a passivation layer 8 is formed (e.g., deposited) on the fourth conductive layer 7.

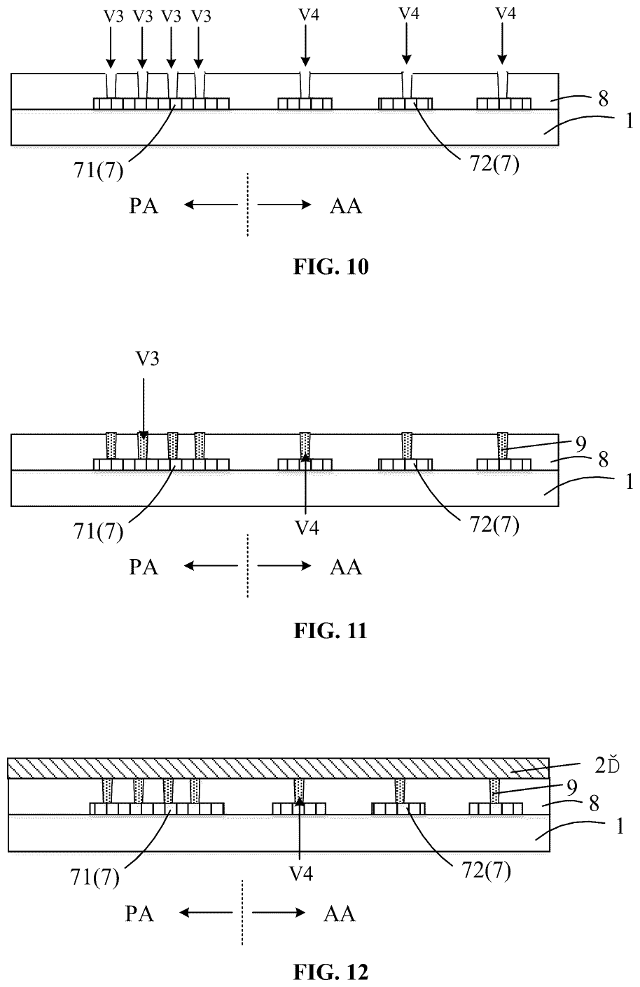

As shown in FIG. 10, the passivation layer is patterned (e.g., etched) to form a first via V3 and a second via V4. The first via exposes a portion of the surface of the first sub-portion 71 away from the substrate 1, and the second via exposes a portion of the surface of the second sub-portion 72 away from the substrate 1.

As shown in FIG. 11, a conductive portion 9 is formed in the first via V3 and the second via V4. The first conductive layer to be formed subsequently can be connected to the first sub-portion 71 through the first via V3, and the second conductive layer to be formed subsequently can be electrically connected to the second sub-portion 72 through the second via V4. The conductive portion 9 may include a metal material. For example, the conductive portion may include tungsten.

As shown in FIG. 12, a first conductive material layer 2’ is formed (e.g., deposited) on the passivation layer 8.

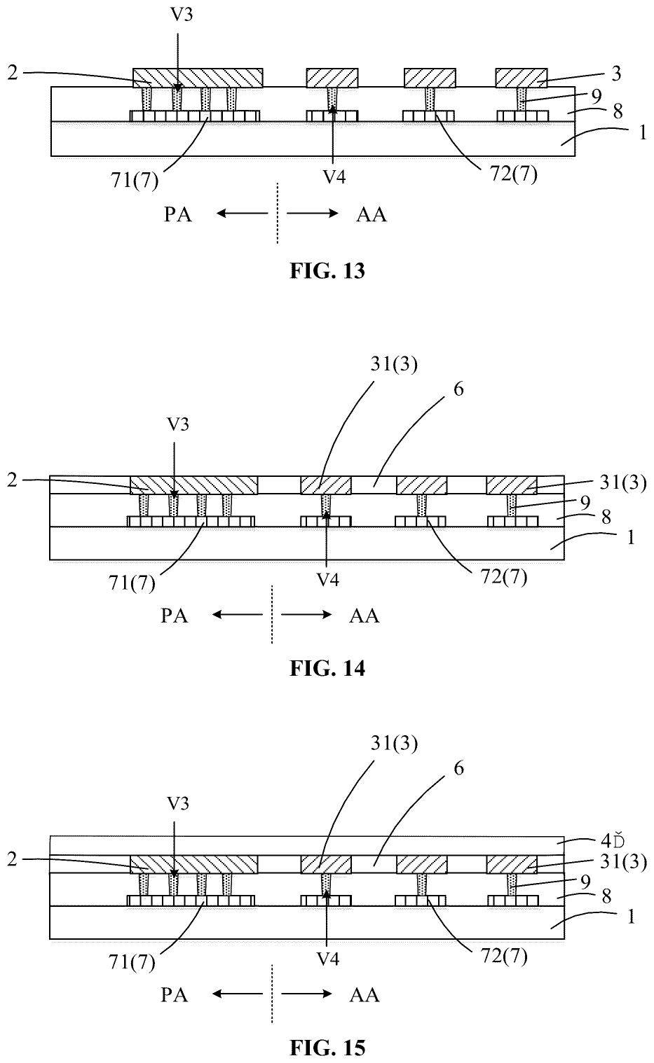

As shown in FIG. 13, the first conductive material layer 2′ is patterned (e.g., etched) to form a first conductive layer 2 and a second conductive layer 3.

As shown in FIG. 14, a planarization layer 6 is formed on the passivation layer, and the planarization layer 6 may fill the removed portion of the first conductive material layer 2′ to separate the first conductive layer and the second conductive layer, and separate the plurality of second sub-conductive portions of the second conductive layer, wherein, the surface of the planarization layer 6 away from the base substrate 1 may be flush with the surface of the first conductive layer 2 away from the base substrate 1 and the surface of the second conductive layer 3 away from the base substrate 1 to provide a flat surface.

As shown in FIG. 15, a pixel define material layer 4′ is formed on the first conductive layer 2, the second conductive layer 3 and the planarization layer 6.

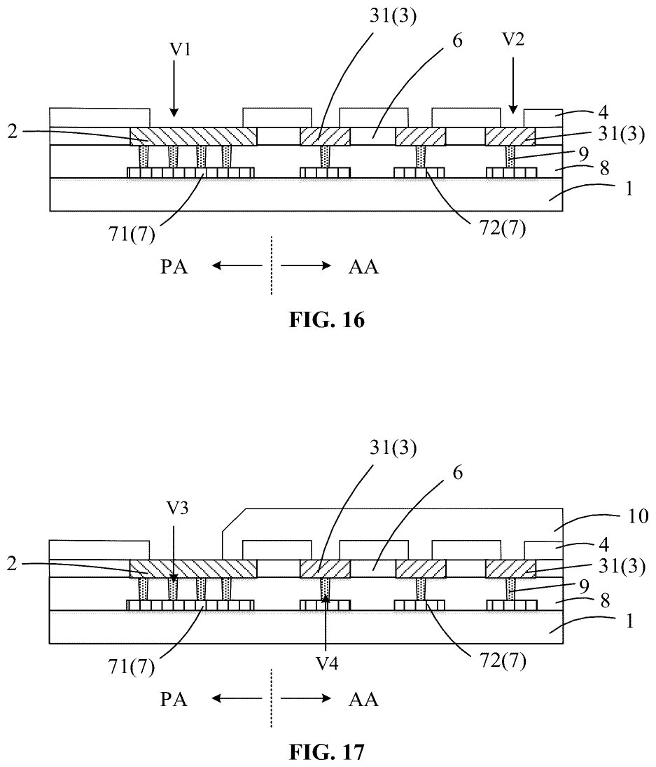

As shown in FIG. 16, the pixel define material layer is patterned to form a first opening V1 and a second opening V2 and a patterned pixel define layer 4.

As shown in FIG. 17, a light-emitting functional layer 10 is formed on the pixel define layer. For example, the light-emitting functional layer can be formed by evaporation.

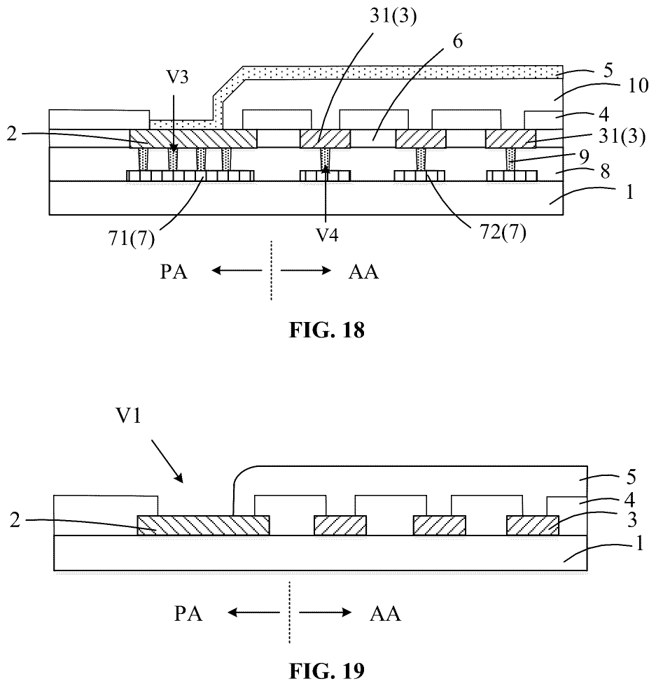

As shown in FIG. 18, a third conductive portion 5 is formed on the light-emitting functional layer 10. For example, the third conductive layer can be formed by evaporation using a mask having an opening corresponding to the first opening V1. In some embodiments, the material of the third conductive layer may include a transparent conductive oxide. For example, the material of the third conductive layer may include indium zinc oxide (IZO).

The array substrate may include at least two first openings. The number of second openings may also be set according to actual needs. The shapes of the first opening, the second opening, the third via hole, and the fourth via hole are not limited to the specific shapes shown in the figures. In some embodiments, the shape may be a polygon, for example, a triangle, a quadrilateral, or a pentagon. In other embodiments, the shape may also be a circle or an ellipse.

Certain specific embodiments have been described, and these embodiments are only shown by way of example and are not intended to limit the scope of the present disclosure. In fact, the novel embodiments described herein can be implemented in various other forms; in addition, various omissions, substitutions and changes in the form of the embodiments described herein can be made without departing from the spirit of the present disclosure. The appended claims and their equivalents are intended to cover such forms or modifications that fall within the scope and spirit of the present disclosure.

1. An array substrate having a display area and a peripheral area at least partially surrounding the display area, the array substrate comprising a base substrate, characterized in that the array substrate further comprises:
a first conductive layer on the base substrate and located in the peripheral area;
a second conductive layer on the base substrate and located in the display area;
a pixel define layer on the first conductive layer and the second conductive layer;
a first opening in the pixel define layer and exposing a portion of a surface of the first conductive layer away from the base substrate;
a second opening in the pixel define layer and exposing a portion of a surface of the second conductive layer away from the base substrate, wherein a width of a bottom of the first opening is greater than a width of a bottom of the second opening;
a third conductive layer on the pixel define layer in the display area, wherein the third conductive layer also extends into the first opening and contacts a side of the first conductive layer away from the base substrate; and
a light-emitting functional layer between the second conductive layer and the third conductive layer, wherein the light-emitting functional layer contacts a side of the first conductive layer away from the base substrate.

2. The array substrate according to claim 1, wherein a contact area between the light-emitting functional layer and the side of the first conductive layer away from the base substrate is smaller than a contact area between the third conductive layer and a side of the first conductive layer away from the base substrate.

3. The array substrate according to claim 1, wherein the first opening and the second opening are formed by a single patterning process.

4. The array substrate according to claim 1, wherein an angle between the first opening and the base substrate is consistent with an angle between the second opening and the base substrate.

5. The array substrate according to claim 4, wherein the angle between the first opening and the base substrate is between 80° and 90°.

6. The array substrate according to claim 1, wherein a width of the first opening is greater than a height of the first opening.

7. The array substrate according to claim 1, wherein the first conductive layer and the second conductive layer are on the same layer.

8. The array substrate according to claim 2, wherein the second conductive layer comprises a plurality of second sub-conductive portions spaced apart from each other, and the array substrate further comprises:
a fourth conductive layer on the base substrate, the fourth conductive layer having a first sub-portion located in the peripheral area and at least one second sub-portion spaced apart from the first sub-portion and located in the display area;
a passivation layer on the fourth conductive layer;
a third via hole and a fourth via hole in the passivation layer, wherein the third via hole is in the peripheral area, and the fourth via hole is in the display area;
a conductive portion in the third via hole and in the fourth via hole, wherein the first conductive layer is electrically connected to the first sub-portion through the third via hole, and wherein the second conductive layer is electrically connected to the second sub-portion through the fourth via hole.

9. The array substrate according to claim 8, wherein an orthographic projection of the first conductive layer on the base substrate at least partially overlaps with an orthographic projection of the first sub-portion on the base substrate with a first overlapping area, wherein an orthographic projection of the third via hole on the base substrate is in the first overlapping area.

10. The array substrate according to claim 8, wherein an orthographic projection of the second conductive layer on the base substrate overlaps at least partially with an orthographic projection of the second sub-portion on the base substrate with a second overlapping area, wherein an orthographic projection of fourth via hole on the base substrate is in the second overlapping area.

11. The array substrate according to claim 1, wherein a side of the light-emitting functional layer close to the peripheral area and a surface of the light-emitting functional layer away from the base substrate are connected by a smooth curved surface.

12. The array substrate according to claim 1, wherein the first opening surrounds the display area.

13. A display device comprising the array substrate according to claim 1.

14. A method for manufacturing an array substrate, the array substrate having a display area and a peripheral area at least partially surrounding the display area, the method comprising providing a base substrate, characterized in that the method further comprises:
forming a first conductive layer in the peripheral area on the base substrate;
forming a second conductive layer in the display area on the base substrate;
forming a pixel define layer on the first conductive layer and the second conductive layer;
forming a first opening in the pixel define layer to expose a portion of a surface of the first conductive layer away from the base substrate;
forming a second opening in the pixel define layer to expose a portion of a surface of the second conductive layer away from the base substrate, wherein a width of the bottom of the first opening is greater than a width of the bottom of the second opening;
forming a third conductive layer in the display area on the pixel define layer, wherein the third conductive layer also extends into the first opening and contacts a side of the first conductive layer away from the base substrate;
forming a light-emitting functional layer between the second conductive layer and the third conductive layer, wherein the light-emitting functional layer contacts a side of the first conductive layer away from the base substrate.

15. The method according to claim 14, wherein forming the first conductive layer, the second conductive layer, the pixel define layer, the first opening and the second opening comprises:
forming a first conductive material layer on the base substrate;
patterning the first conductive material layer to form the first conductive layer and the second conductive layer;
forming a pixel define material layer on the first conductive layer and the second conductive layer;
patterning the pixel define material layer to form the first opening and the second opening, the method further comprises:
before forming the first conductive material layer,
forming a fourth conductive material layer on the base substrate;
patterning the fourth conductive material layer to form a fourth conductive layer, wherein the fourth conductive layer has a first sub-portion in the peripheral area and at least one second sub-portion in the display area and spaced apart from the first sub-portion;
forming a passivation layer on the fourth conductive layer;
patterning the passivation layer to form a third via hole and a fourth via hole, wherein the third via hole exposes a portion of a surface of the first sub-portion away from the base substrate, and the fourth via hole exposes a portion of a surface of the second sub-portion away from the base substrate;
forming a conductive portion in the third via hole and the fourth via hole, wherein the first conductive layer is connected to the first sub-portion through the third via hole, and wherein the second conductive layer is electrically connected to the second sub-portion through the fourth via hole; and
after forming the first opening and the second opening,
forming a light-emitting functional layer on the pixel define layer;
forming the third conductive portion on the light-emitting functional layer.

16. The display device comprising the array substrate according to claim 13, wherein a contact area between the light-emitting functional layer and the side of the first conductive layer away from the base substrate is smaller than a contact area between the third conductive layer and a side of the first conductive layer away from the base substrate.

17. The display device comprising the array substrate according to claim 13, wherein he first opening and the second opening are formed by a single patterning process.

18. The display device comprising the array substrate according to claim 13, wherein an angle between the first opening and the base substrate is consistent with an angle between the second opening and the base substrate.

19. The display device comprising the array substrate according to claim 18, wherein the angle between the first opening and the base substrate is between 80° and 90°.

20. The display device comprising the array substrate according to claim 13, wherein a width of the first opening is greater than a height of the first opening.
